(19) United States
(12) Patent Application Publication
(10) Pub. No.: US 2025/0386509 A1
(43) Pub. Date: Dec. 18, 2025

(54) SEMICONDUCTOR DEVICES

(71) Applicants: SAMSUNG ELECTRONICS CO., LTD., Suwon-si (KR); POSTECH RESEARCH AND BUSINESS DEVELOPMENT FOUNDATION, Pohang-si (KR)

(72) Inventors: Yoonyoung CHUNG, Pohang-si (KR); Seongmin Park, Incheon (KR)

(73) Assignees: SAMSUNG ELECTRONICS CO., LTD., Suwon-si (KR); POSTECH RESEARCH AND BUSINESS DEVELOPMENT FOUNDATION, Pohang-si (KR)

(21) Appl. No.: 19/217,531

(22) Filed: May 23, 2025

(30) Foreign Application Priority Data
Jun. 12, 2024 (KR) 10-2024-0076322
Aug. 6, 2024 (KR) 10-2024-0104365

(51) Int. Cl. H10B 43/35; G11C 16/04; G11C 16/10; G11C 16/14; H10B 43/27; H10D 30/01; H10D 30/69; H10D 62/80

(52) U.S. Cl. CPC H10B 43/35; G11C 16/0466; G11C 16/105; G11C 16/14; H10B 43/27; H10D 30/693; H10D 30/696; H10D 62/875; H10D 30/0413

(57) ABSTRACT

Provided is a flash memory device including a first gate electrode including a semiconductor material, a tunnel insulating pattern in contact with an upper surface of the first gate electrode, a charge trapping pattern on the tunnel insulating pattern, a blocking pattern on the charge trapping pattern, a channel on the blocking pattern, the channel including an oxide semiconductor material, source/drain patterns on the channel, the source/drain patterns being spaced apart from each other, and a second gate electrode in contact with the channel, the second gate electrode being between adjacent source/drain patterns of the source/drain patterns.

### CROSS-REFERENCE TO RELATED APPLICATION

This application claims priority to Korean Patent Application No. 10-2024-0076322 filed on Jun. 12, 2024 and No. 10-2024-0104365 filed on Aug. 6, 2024 in the Korean Intellectual Property Office, the disclosure of which is hereby incorporated by reference in its entirety.

### TECHNICAL FIELD

Embodiments of the present disclosure relate to a semiconductor device. More particularly, the inventive concepts relate to a flash memory device.

### DESCRIPTION OF RELATED ART

In order to store a relatively large amount of data, a flash memory device has a three-dimensional (3D) structure, and a channel used in the flash memory device includes polysilicon instead of single-crystal silicon. Thus, a mobility of a carrier included in the channel decreases, and electrical characteristics of the channel are not uniform according to heights thereof.

An oxide semiconductor material may be used for the channel instead of polysilicon, however, as the oxide semiconductor material has a low concentration and a low mobility of a minority carrier, an erase operation of the flash memory device is not easily performed.

### SUMMARY

One or more embodiments provide a semiconductor device having improved characteristics.

According to an aspect of one or more embodiments, there is provided a flash memory device including a first gate electrode including a semiconductor material, a tunnel insulating pattern in contact with an upper surface of the first gate electrode, a charge trapping pattern on the tunnel insulating pattern, a blocking pattern on the charge trapping pattern, a channel on the blocking pattern, the channel including an oxide semiconductor material, source/drain patterns on the channel, the source/drain patterns being spaced apart from each other, and a second gate electrode in contact with the channel, the second gate electrode being between adjacent source/drain patterns of the source/drain patterns.

According to another aspect of one or more embodiments, there is provided a flash memory device including a gate electrode including a semiconductor material, a hole tunnel insulating pattern in contact with an upper surface of the gate electrode, a charge trapping pattern on the hole tunnel insulating pattern, an electron tunnel insulating pattern on the charge trapping pattern, a channel in contact with an upper surface of the electron tunnel insulating pattern, the channel including an oxide the semiconductor material, and source/drain patterns on the channel, the source/drain patterns being spaced apart from each other, wherein based on a program voltage with a first positive value being applied to the gate electrode, electrons included in the channel is configured to move to the charge trapping pattern through the electron tunnel insulating pattern and be trapped in the charge trapping pattern, to perform a program operation, and wherein based on an erase voltage with a second positive value smaller than the first positive value being applied to the gate electrode, holes included in the gate electrode are configured to move to the charge trapping pattern through the hole tunnel insulating pattern, to perform an erase operation.

According to still another aspect of one or more embodiments, there is provided a flash memory device including a first gate electrode on a substrate, the first gate electrode extending in a vertical direction perpendicular to an upper surface of the substrate, a channel in contact with a sidewall and a lower surface of the first gate electrode, a memory structure including a blocking pattern, an electron trapping pattern, and a tunnel insulating pattern sequentially stacked in a horizontal direction parallel to the upper surface of the substrate from an outer sidewall of the channel, and gate electrode structures spaced apart from each other in the vertical direction on the substrate, each of the gate electrode structures on the memory structure.

### BRIEF DESCRIPTION OF DRAWINGS

Embodiments will be more clearly understood from the following detailed description taken in conjunction with the accompanying drawings in which:

FIG. 1 is a cross-sectional view illustrating a memory cell structure of a flash memory device according to one or more embodiments;

FIGS. 2 and 3 are a mimetic diagram and an energy band diagram, respectively, illustrating a programming method of the memory cell structure of the flash memory device.

FIGS. 4 and 5 are a mimetic diagram and an energy band diagram, respectively, illustrating an erasing method of the memory cell structure of the flash memory device;

FIG. 6 is a graph illustrating characteristics of program operation and erase operation of the memory cell structure of the flash memory device illustrated in FIG. 1;

FIG. 7 is a cross-sectional view illustrating a memory cell structure of a flash memory device in accordance with a first related embodiment;

FIG. 8 is a graph illustrating characteristics of program operation and erase operation of the memory cell structure of the flash memory device illustrated in FIG. 7;

FIG. 9 is a graph illustrating an electric potential of a channel 62 when a negative voltage is applied to a first gate electrode 12 included in the memory cell structure of the flash memory device illustrated in FIG. 7;

FIG. 10 is a cross-sectional view illustrating a memory cell structure of a flash memory device in accordance with a second related embodiment;

FIG. 11 is a graph illustrating a characteristic of program operation of the memory cell structure of the flash memory device illustrated in FIG. 10.

FIG. 12 is a cross-sectional view illustrating a memory cell structure of a flash memory device according to one or more embodiments.

FIG. 13 is a mimetic diagram illustrating a programming method and an erasing method of the memory cell structure of the flash memory device illustrated in FIG. 12, and

FIGS. 14 and 15 are energy band diagrams of program operation and erase operation, respectively;

FIG. 16 is a graph illustrating characteristics of program operation and erase operation of the memory cell structure of the flash memory device illustrated in FIG. 12;

FIGS. 17 and 18 are graphs illustrating characteristics of program operation and erase operation of the memory cell structure of the flash memory device illustrated in FIG. 12;

FIG. 19 is a cross-sectional view illustrating a vertical NAND flash memory device according to one or more embodiments;

FIGS. 20, 21, 22, 23, 24, 25, 26, and 27 are the cross-sectional views illustrating a method of manufacturing a vertical NAND flash memory device according to one or more embodiments; and

FIG. 28 is a cross-sectional view illustrating a vertical NAND flash memory device according to one or more embodiments.

### DETAILED DESCRIPTION

The above and other aspects and features of a semiconductor device and a method of manufacturing the same according to one or more embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings of inventive concepts.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

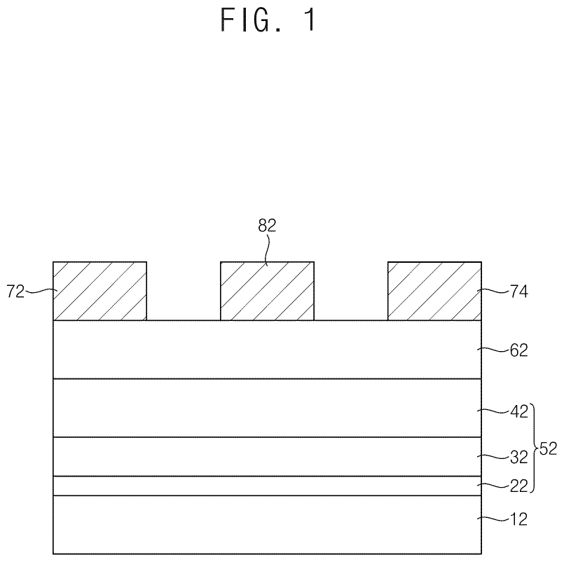

FIG. 1 is a cross-sectional view illustrating a memory cell structure of a flash memory device according to one or more embodiments.

Referring to FIG. 1, the memory cell structure may include a first gate electrode 12, a first memory structure 52 and a channel 62 sequentially stacked in a vertical direction, a first source/drain pattern 72, a second source/drain pattern 74, and a second gate electrode 82 spaced apart from each other in a horizontal direction on the channel 62.

In one or more embodiments, the first gate electrode 12 may include a semiconductor material, e.g., silicon, germanium, silicon-germanium, etc., and the semiconductor material may not be doped, or may be doped with, e.g., n-type impurities, p-type impurities. The first gate electrode 12 may also be referred to as a front gate electrode.

In one or more embodiments, the first memory structure 52 may include a tunnel insulating pattern 22, a charge trapping pattern 32, and a blocking pattern 42 sequentially stacked in the vertical direction.

The tunnel insulating pattern 22 may include, e.g., silicon oxide, the charge trapping pattern 32 may include, e.g., silicon nitride, and the blocking pattern 42 may include a metal oxide, e.g., aluminum oxide.

However, embodiments are not limited thereto. For example, the tunnel insulating pattern 22 may include a metal oxide, e.g., aluminum oxide, and the blocking pattern 42 may include, e.g., silicon oxide. Thus, the tunnel insulating pattern 22 and the blocking pattern 42 may include different insulating materials from each other, or a same insulating material.

In one or more embodiment, each of the tunnel insulating pattern 22 and the blocking pattern 42 may have a multi-layered structure of a first layer including, e.g., silicon oxide and a second layer including a metal oxide, e.g., aluminum oxide.

In one or more embodiments, the blocking pattern 42 may have a thickness in the vertical direction greater than a thickness of the tunnel insulating pattern 22.

In example embodiments, the channel 62 may include an oxide semiconductor material with a relatively high band gap. The oxide semiconductor material may include at least one of zinc tin oxide (ZTO), indium zinc oxide (IZO), zinc oxide (ZnOₓ), indium gallium zinc oxide (IGZO), indium gallium silicon oxide (IGSO), Indium oxide (InOₓ, In₂O₃), tin oxide (SnO₂), titanium oxide (TiOₓ), zinc oxide nitride (ZnₓO_{y}N₂), magnesium zincoxide (MgₓZn_{y}O_{z}), indium zinc oxide (InₓZn_{y}Oₐ), indium gallium zinc oxide (InₓGa_{y}Zn_{z}Oₐ), zirconium indium zinc oxide (ZrₓIn_{y}Zn₂Oₐ), hafnium indium zinc oxide (HfₓIn_{y}Zn_{z}Oₐ), tin indium zinc oxide (SnₓIn_{y}Zn_{z}Oₐ), aluminum tin indium zinc oxide (AlₓSn_{y}In_{z}Zn_{z}Oₐ), silicon indiumzinc oxide (SiₓIn_{y}Zn_{z}Oₐ), zinc tin oxide (ZnₓSn_{y}O_{z}), aluminum zinc tin oxide (AlₓZn_{y}Sn_{z}Oₐ), gallium zine tin oxide (GaₓZn_{y}Sn_{z}Oₐ), zirconium zine tin oxide (ZrₓZn_{y}Sn_{z}Oₐ) and indium gallium silicon oxide (InGaSiO).

Each of the first and second source/drain patterns 72 and 74 and the second gate electrode 82 may include a metal, e.g., aluminum. In an example embodiment, each of the first and second source/drain patterns 72 and 74 and the second gate electrode 82 may have a multi-layered structure of a first electrode layer including, e.g., molybdenum and a second electrode layer including, e.g., aluminum, however, embodiments are not limited thereto.

According to another embodiment, each of the first and second source/drain patterns 72 and 74 and the second gate electrode 82 may include, e.g., polysilicon or single crystal silicon doped with n-type impurities or p-type impurities.

The second gate electrode 82 may also be referred to as a back gate electrode.

In one or more embodiments, an insulating pattern including, e.g., silicon oxide and having a thickness equal to or less than about 2 nm may be further disposed between the channel 62, and each of the first and second source/drain patterns 72 and 74 and the second gate electrode 82.

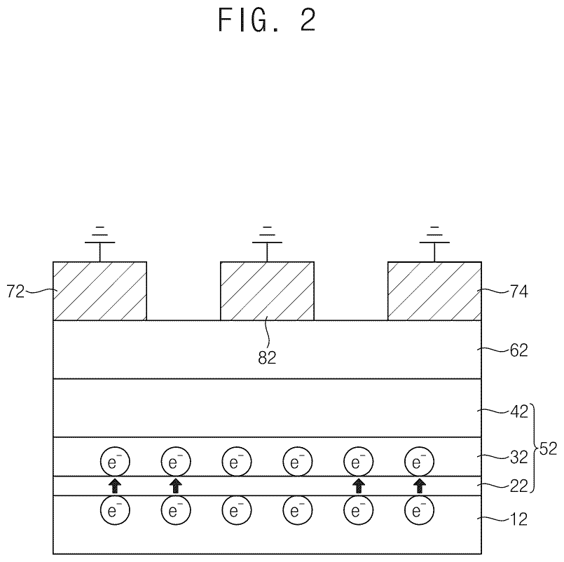

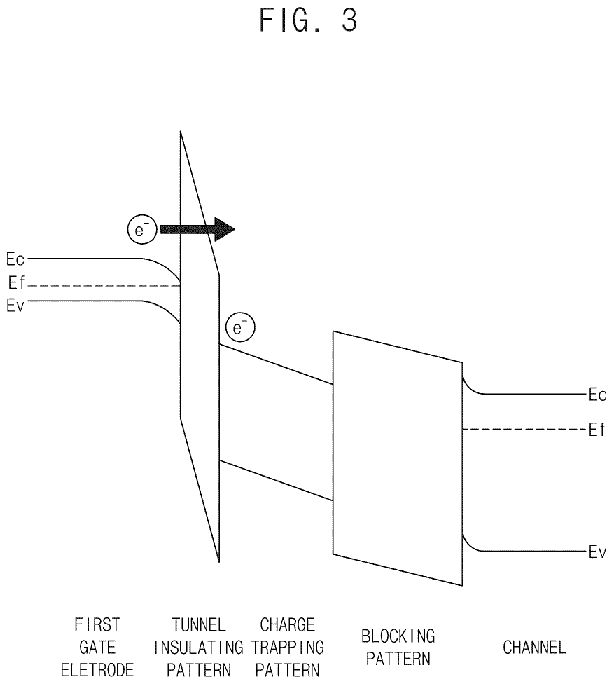

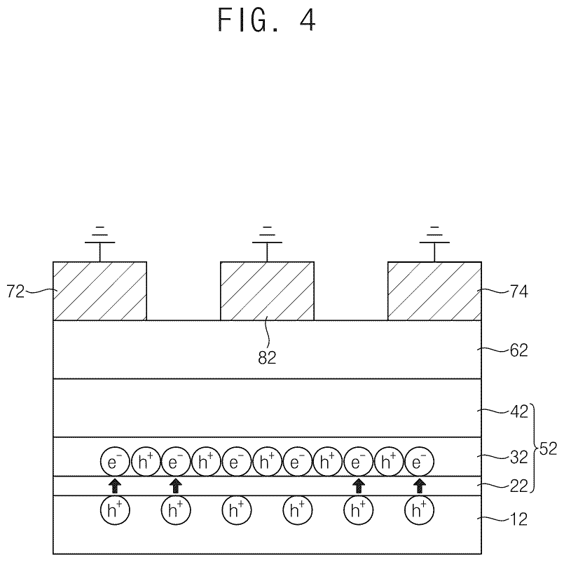

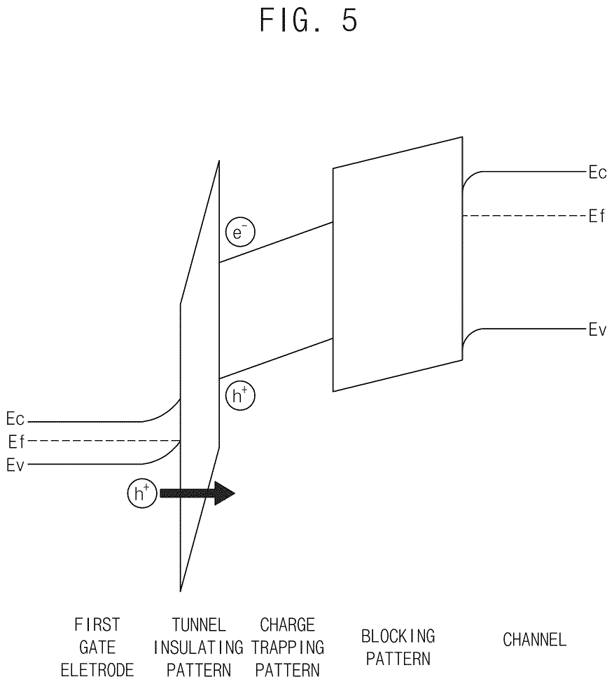

FIGS. 2 and 3 are a mimetic diagram and an energy band diagram, respectively, illustrating a programming method of the memory cell structure of the flash memory device. FIGS. 4 and 5 are a mimetic diagram and an energy band diagram, respectively, illustrating an erasing method of the memory cell structure of the flash memory device.

Referring to FIGS. 2 and 3, a negative program voltage (−V_{P}) may be applied to the first gate electrode 12, and a ground voltage (0V) may be applied to the second gate electrode 82.

Thus, electrons included in the first gate electrode 12 including the semiconductor material may move to the charge trapping pattern 32 through the tunnel insulating pattern 22 that may have a relatively thin thickness and contact the first gate electrode 12, and may be trapped in the charge trapping pattern 32. Thus, the memory cell structure may be programmed.

Holes may exist in the channel 62 including the oxide semiconductor material, however, a concentration and a mobility of the holes may be significantly low, and the blocking pattern 42 contacting the channel 62 may have a relatively thick thickness, and thus, even when the program voltage (−V_{P}) is applied to the first gate electrode 12, the holes may not move to the charge trapping pattern 32 from the channel 62 by the program voltage (−V_{P}).

As the second gate electrode 82 is grounded, even when the program voltage (−V_{P}) is applied to the first gate electrode 12, a potential of the channel 62 may be fixed and maintained to 0V, instead of having a negative value.

Referring to FIGS. 4 and 5, an erase voltage (+V_{E}) having a positive value may be applied to the first gate electrode 12, and the second gate electrode 82 may be maintained in a grounded state, so that the potential of the channel 62 contacting to the second gate electrode 82 may also be fixed and maintained to 0V.

Thus, the holes in the first gate electrode 12 including the semiconductor material may move to the charge trapping pattern 32 through the tunnel insulating pattern 22 that may have the relatively thin thickness and contact the first gate electrode 12, and may be recombined with electrons of the charge trapping pattern 32 to be annihilated, so that the memory cell structure may be erased.

Electrons may exist in the channel 62 including the oxide semiconductor material, and thus, as the erase voltage is applied to the first gate electrode 12, some of the electrons in the channel 62 may move to the charge trapping pattern 32 through the blocking pattern 42. However, the blocking pattern 42 contacting the channel 62 may have the thickness greater than that of the tunnel insulating pattern 22, so that an amount of electrons that may move to the charge trapping pattern 32 from the channel 62 through the blocking pattern 42 due to the erase voltage (+V_{E}) applied to the first gate electrode 12 may be significantly small.

In one or more embodiments, an absolute value of the erase voltage (+V_{E}) may be less than that of the program voltage (−Vₚ). When the erase voltage (+V_{E}) is applied to the first gate electrode 12, the electrons in the channel 62 may cause an effect in which an electric field is substantially applied only to the first memory structure 52. However, when the program voltage (−Vₚ) is applied to the first gate electrode 12, almost no holes may exist in the channel 62, resulting in an effect in which the electric field may be applied not only to the first memory structure 52 but also to the channel 62.

Thus, even when, for example, a same voltage is applied to the first gate electrode 12, when the erase voltage (+V_{E}) is applied, a relatively high electric field may be applied to the tunnel insulating pattern 22 included in the first memory structure 52, compared to when the program voltage (−Vₚ) is applied. Accordingly, even when the absolute value of the erase voltage (+V_{E}) is less than that of the program voltage (−Vₚ), erase operation may be easily performed.

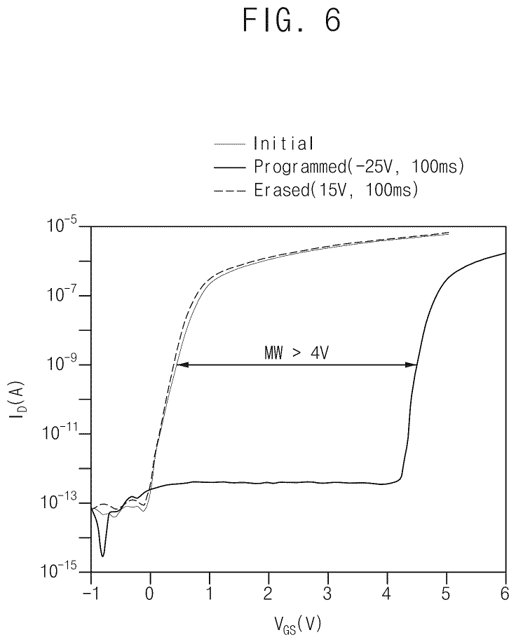

FIG. 6 is a graph illustrating characteristics of program operation and erase operation of the memory cell structure of the flash memory device illustrated in FIG. 1. Particularly, FIG. 6 is a graph illustrating drain current (I_{P}) with respect to gate source voltage (V_{GS}).

In the memory cell structure of the flash memory device, the first gate electrode 12 included polysilicon, the tunnel insulating pattern 22 included silicon oxide and had a thickness of about 3.5 nm, the charge trapping pattern 32 included silicon nitride and had a thickness of about 10 nm, the blocking pattern 42 included aluminum oxide and had a thickness of about 10 nm, and the channel 62 included IGZO and had a thickness of about 10 nm.

A programming pulse of about −25V voltage was applied to the first gate electrode 12 included in the memory cell structure of the flash memory device for about 100 ms, an erasing pulse of about +15V voltage was applied to the first gate electrode 12 for about 100 ms, and the second gate electrode 82 was maintained in a grounded state.

Referring to FIG. 6, as the programming pulse is applied, a threshold voltage of the memory cell structure is shifted in a positive direction by about 4V, and as the erasing pulse is applied, the threshold voltage of the memory cell structure is shifted in a negative direction by about 4V, so that the threshold voltage returns to an initial state.

The program operation and the erase operation to the memory cell structure of the flash memory device may be performed more effectively, and the flash memory device has a memory window of about 4V.

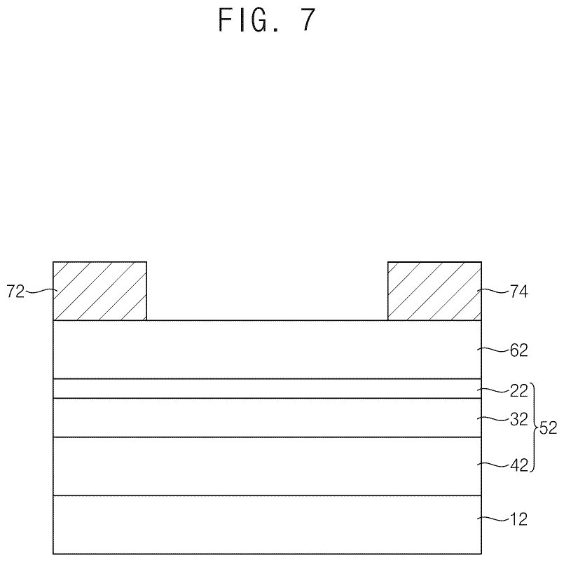

FIG. 7 is a cross-sectional view illustrating a memory cell structure of a flash memory device in accordance with a first related embodiment.

Referring to FIG. 7, the memory cell structure may include the first gate electrode 12, the first memory structure 52 and the channel 62 sequentially stacked in the vertical direction on the first gate electrode 12, and the first and second source/drain patterns 72 and 74 on the channel 62.

The memory cell structure may not include the second gate electrode 82, that is, the back gate electrode.

The first memory structure 52 may include the blocking pattern 42, the charge trapping pattern 32, and the tunnel insulating pattern 22 sequentially stacked in the vertical direction.

Each of the first gate electrode 12 and the first and second source/drain patterns 72 and 74 may include, e.g., a metal, a metal nitride, a metal silicide, etc., each of the tunnel insulating pattern 22 and the blocking pattern 42 may include, e.g., silicon oxide or aluminum oxide, the charge trapping pattern 32 may include, e.g., silicon nitride, and the channel 62 may include an oxide semiconductor material with a relatively high band gap, e.g., IGZO.

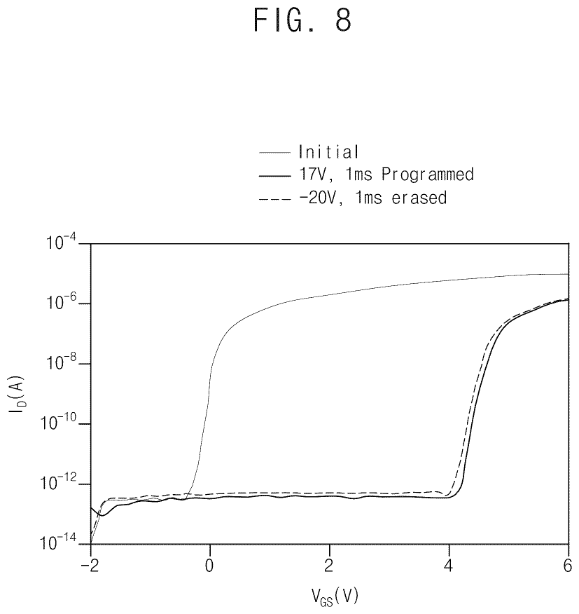

FIG. 8 is a graph illustrating characteristics of program operation and erase operation of the memory cell structure of the flash memory device illustrated in FIG. 7. Particularly, FIG. 8 is a graph illustrating drain current (I_{P}) with respect to gate source voltage (V_{GS}).

In the memory cell structure of the flash memory device, the first gate electrode 12 included aluminum, the tunnel insulating pattern 22 included aluminum oxide and had a thickness of about 3 nm, the charge trapping pattern 32 included silicon nitride and had a thickness of about 10 nm, the blocking pattern 42 included aluminum oxide and had a thickness of about 10 nm, and the channel 62 included IGZO and may had a thickness of about 30 nm.

A programming pulse of +17V voltage was applied to the first gate electrode 12 included in the memory cell structure of the flash memory device for about 1 ms, and an erasing pulse of −20V voltage was applied to the first gate electrode 12 for about 1 ms.

Referring to FIG. 8, as the programming pulse is applied, a threshold voltage of the memory cell structure is shifted in a positive direction by about 4V, and even the erasing pulse is applied, the threshold voltage of the memory cell structure is not shifted.

The program operation to the memory cell structure of the flash memory device may be performed more effectively, however, the erase operation to the memory cell structure may not be performed effectively.

The electrons may be distributed in a relatively high density in the channel 62 including the oxide semiconductor material with the relatively high band gap and the mobility of the electrons may be relatively high, while the holes may be distributed in a relatively low density and the mobility of the holes may be relatively low, so that even when the erase voltage with the negative value is applied to the first gate electrode 12, the holes may not move to the charge trapping pattern 32 from the channel 62 through the tunnel insulating pattern 22.

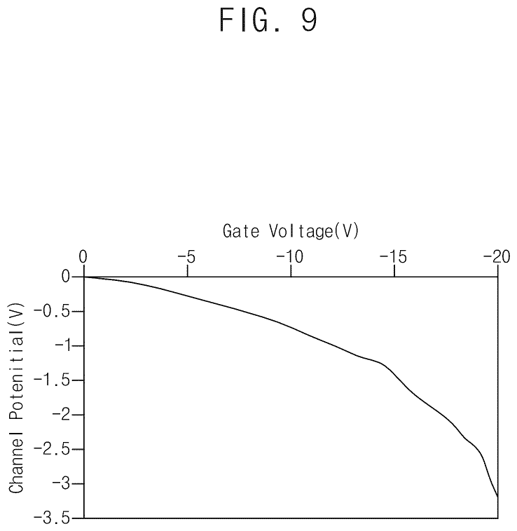

When the erase voltage with the negative value is applied to the first gate electrode 12, the oxide semiconductor material included in the channel 62 may be depleted so that the channel 62 may be in a floating state, and that a significantly small voltage may be applied to the channel 62, which may be further illustrated below with reference to FIG. 9.

FIG. 9 is a graph illustrating an electric potential of the channel 62 when the negative voltage is applied to the first gate electrode 12 included in the memory cell structure of the flash memory device illustrated in FIG. 9.

Referring to FIG. 9, as an absolute value of a negative voltage applied to the first gate electrode 12 increases, an absolute value of a negative potential of the channel 62 also increases.

When the negative voltage is applied to the first gate electrode 12, each of the first and second source/drain patterns 72 and 74 is maintained at about 0V, while the potential of the channel 62 is not maintained at 0V, and has a negative potential corresponding to the negative voltage. Thus, a potential difference between the first gate electrode 12 and the channel 62 is significantly small so that a significantly small electric field is applied to the tunnel insulating pattern 22 between the first gate electrode 12 and the channel 62, and that the holes hardly move to the charge trapping pattern 32 from the channel 62 through the tunnel insulating pattern 22.

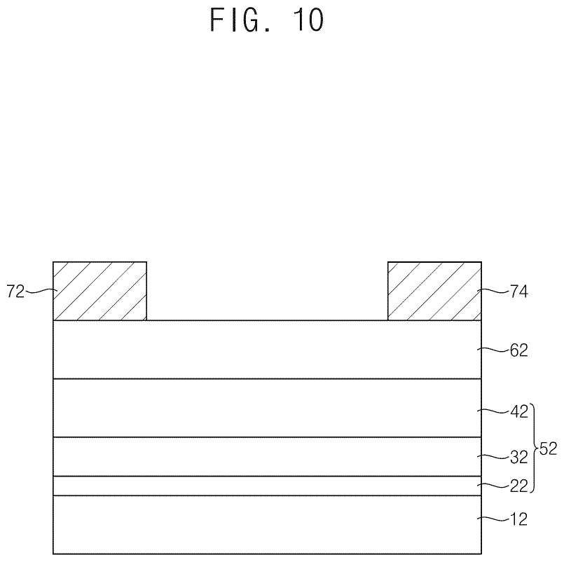

FIG. 10 is a cross-sectional view illustrating a memory cell structure of a flash memory device in accordance with a second related embodiment.

This memory cell structure of the flash memory device may be substantially the same as or similar to that of FIG. 1 except for not including the second gate electrode 82, that is, the back gate electrode, and thus repeated explanations are omitted herein.

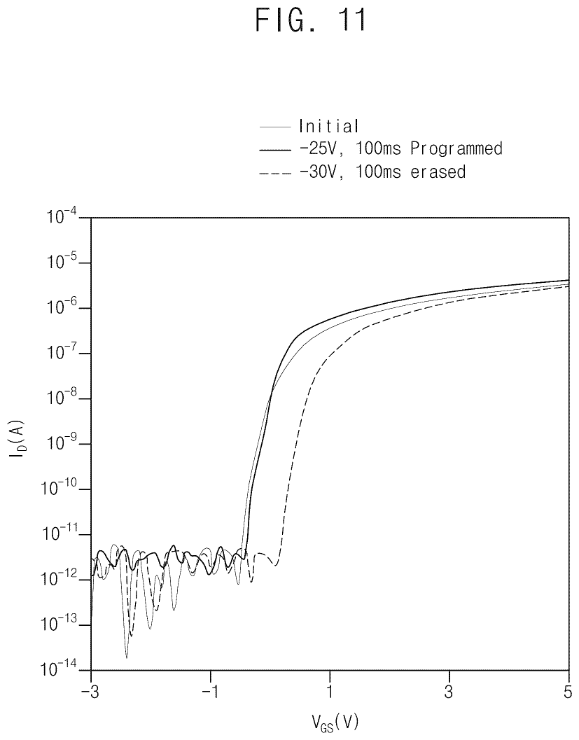

FIG. 11 is a graph illustrating characteristics of program operation of the memory cell structure of the flash memory device illustrated in FIG. 10. Particularly, FIG. 11 is a graph illustrating drain current (I_{P}) with respect to gate source voltage (V_{GS}).

This memory cell structure of the flash memory device had the same structure, size, and material with the structure, size, and material of the memory cell structure of the flash memory device in FIG. 6, except for the second gate electrode.

A first programming pulse of about −25V was applied to the first gate electrode 12 included in the memory cell structure of the flash memory device for about 100 ms, and a second programming pulse of about −30V was applied for about 100 ms.

Referring to FIG. 11, even though the first programming pulse is applied, the threshold voltage of the memory cell structure nearly remains unchanged, and when the second programming pulse is applied, a significantly small threshold voltage shift of about 0.5V occurs.

Program operation to the memory cell structure of the flash memory device may not be performed more effectively. Similar to FIG. 9, when the program voltage with the negative value is applied to the first gate electrode 12, the channel 62 becomes in a floating state, and a very small electric field is applied to the tunnel insulating pattern 22, so that the electrons hardly move to the charge trapping pattern 32 from the first gate electrode 12 through the tunnel insulating pattern 22.

As a result, the erase operation and the program operation may not be properly performed through the memory cell structures of the flash memory devices according to the first and second comparative examples.

However, according to one or more embodiments, the memory cell structure of the flash memory device may include the first gate electrode 12 including the semiconductor material, the tunnel insulating pattern 22 having the relatively thin thickness and contacting the first gate electrode 12, the channel 62 including the oxide semiconductor material with the relatively high band gap, the blocking pattern 42 having the relatively thick thickness and contacting the channel 62, and the second gate electrode 82 disposed on the channel 62. The second gate electrode 82 may be in a grounded state, and the program voltage with the negative value and the erase voltage with the positive value may be applied to the first gate electrode 12.

Thus, when the program voltage is applied, the channel 62 may be floated by the second gate electrode 82 and be maintained at the potential of 0V instead of having the negative potential, so that a sufficiently large electric field may be applied to the tunnel insulating pattern 22, and that the electrons may move from the first gate electrode 12 through the tunnel insulating pattern 22 to be trapped in the charge trapping pattern 32. Thus, the program operation through the memory cell structure may be performed more effectively.

When the erase voltage is applied, some of the electrons may move to the charge trapping pattern 32 from the channel 62 through the blocking pattern 42, however, as the tunnel insulating pattern 22 has the thickness smaller than a thickness of the blocking pattern 42, an amount of the holes moving through the tunnel insulating pattern 22 to the charge trapping pattern 32 may be greater than an amount of the electrons moving through the blocking pattern 42 to the charge trapping pattern 32, so that the erase operation through the memory cell structure may be performed more effectively.

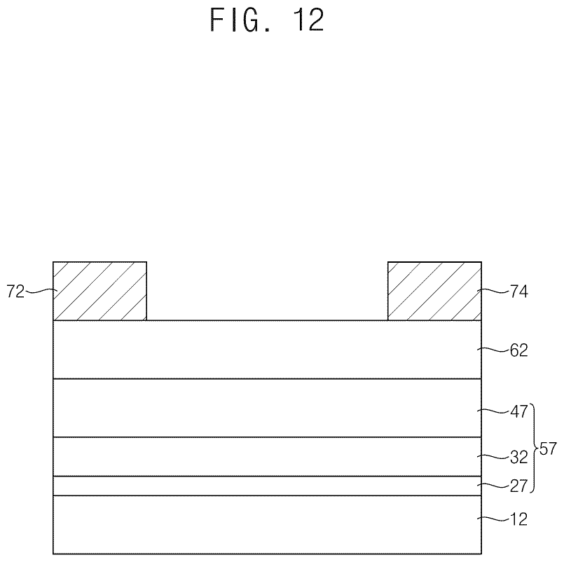

FIG. 12 is a cross-sectional view illustrating a memory cell structure of a flash memory device according to one or more embodiments. This memory cell structure may be substantially the same as or similar to that of FIG. 1, except for some elements, and thus repeated explanations are omitted herein.

Referring to FIG. 12, the memory cell structure may include the first gate electrode 12, a second memory structure 57 and the channel 62 sequentially stacked in the vertical direction, and the first and second source/drain patterns 72 and 74 spaced apart from each other in the horizontal direction on the channel 62.

In one or more embodiments, the first gate electrode 12 may include a semiconductor material, and the channel 62 may include an oxide semiconductor material with a relatively high band gap.

In one or more embodiments, the second memory structure 57 may include a hole tunnel insulating pattern 27, the charge trapping pattern 32, and an electron tunnel insulating pattern 47 sequentially stacked in the vertical direction.

Each of the hole tunnel insulating pattern 27 and the electron tunnel insulating pattern 47 may include, e.g., silicon oxide or a metal oxide such as aluminum oxide. In one or more embodiments, the electron tunnel insulating pattern 47 may have a thickness greater than a thickness of the hole tunnel insulating pattern 27 in the vertical direction.

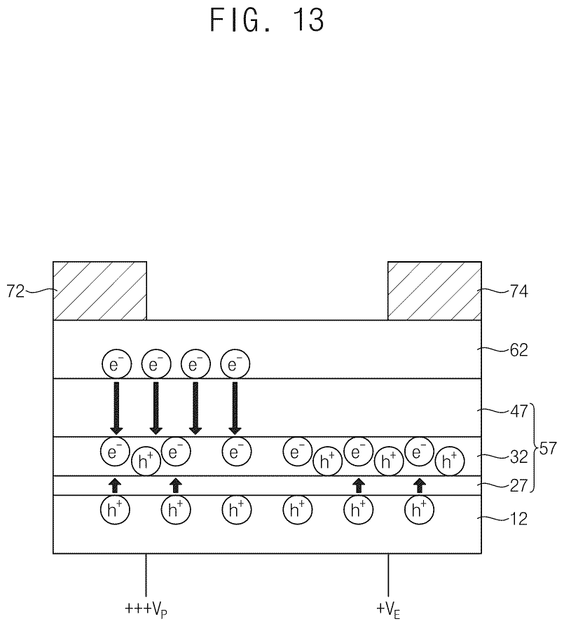

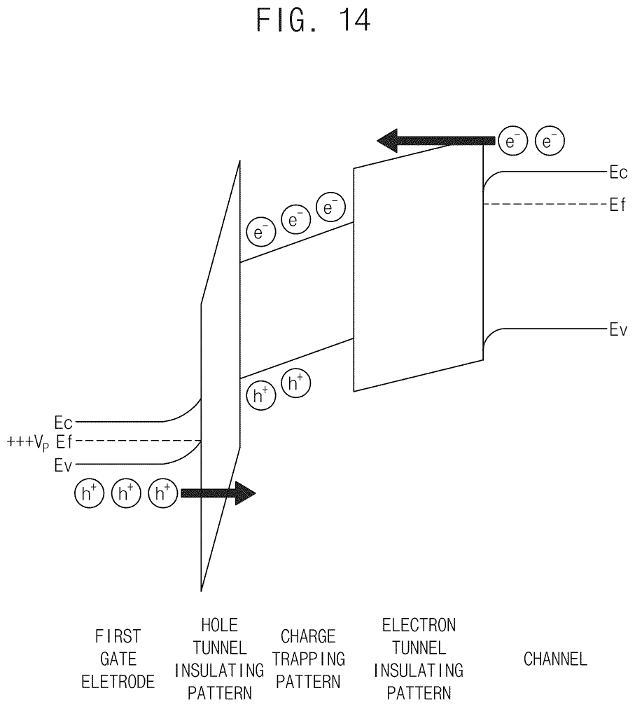

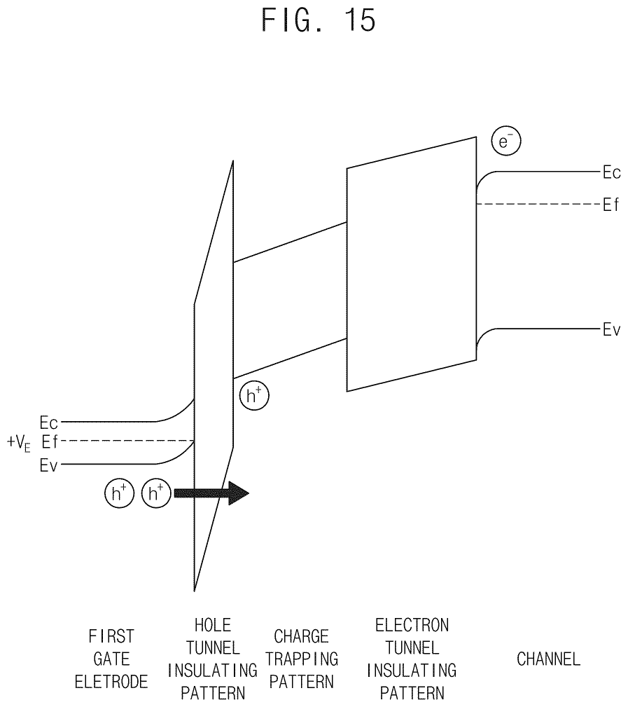

FIG. 13 is a mimetic diagram illustrating a programming method and an erasing method of the memory cell structure of the flash memory device illustrated in FIG. 12. FIGS. 14 and 15 are energy band diagrams of program operation and erase operation, respectively.

Referring to FIGS. 13 and 14, a program voltage (+++Vₚ) with a first positive value may be applied to the first gate electrode 12.

Thus, electrons included in the channel 62 including the oxide semiconductor material may move to the charge trapping pattern 32 through the electron tunnel insulating pattern 47 contacting the channel 62, and be trapped in the electron tunnel insulating pattern 47, so that the memory cell structure may be programmed.

Holes may exist in the first gate electrode 12 including the semiconductor material, and thus, as the program voltage is applied, some of the holes may move to the charge trapping pattern 32 through the hole tunnel insulating pattern, however, a current density by the electrons moving through the electron tunnel insulating pattern 47 may be greater than that of the holes moving through the hole tunnel insulating pattern 27, so that the program operation may be performed.

Referring to FIGS. 13 and 15, an erase voltage (+V_{E}) having a second positive value smaller than the first positive value may be applied to the first gate electrode 12.

Thus, the holes in the first gate electrode 12 including the semiconductor material may move to the charge trapping pattern 32 through the hole tunnel insulating pattern 27 contacting the first gate electrode 12, and may be recombined with the electrons in the charge trapping pattern 32 to be annihilated, so that the memory cell structure may be erased.

Electrons may exist in the channel 62 including oxide semiconductor material, and thus, as the erase voltage is applied, some of the electrons may move to the charge trapping pattern 32 through the electron tunnel insulating pattern 47. However, the electron tunnel insulating pattern 47 contacting the channel 62 may have a thickness greater than a thickness of the hole tunnel insulating pattern 27, so that an amount of the electrons moving through the electron tunnel insulating pattern 47 may be significantly small. Accordingly, the erase operation may be performed.

As a result, in the memory cell structure of the flash memory device, the electrons in the channel 62 with a relatively high band gap may move to the charge trapping pattern 32 through the electron tunnel insulating pattern 47 by the program voltage with a relatively high positive value, so that the program operation may be performed. The holes in the first gate electrode 12 with a relatively low band gap may move to the charge trapping pattern 32 through the hole tunnel insulating pattern 27 by the erase voltage with a relatively low positive value, so that the erase operation may be performed

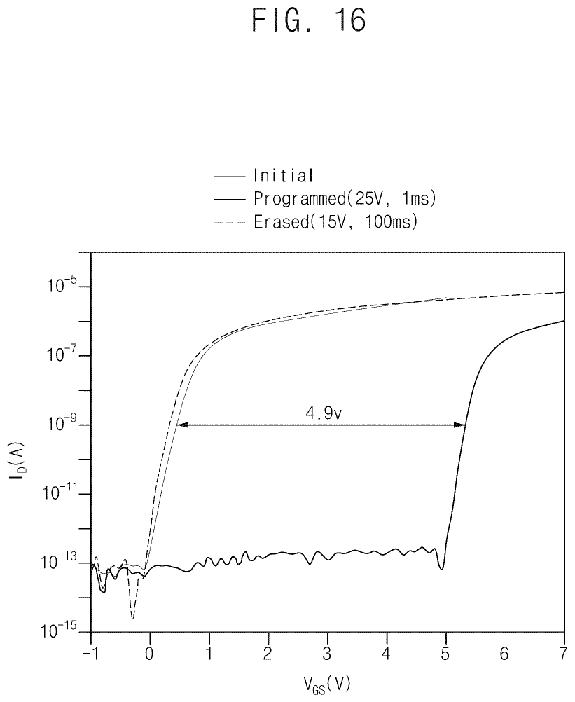

FIG. 16 is a graph illustrating characteristics of program operation and erase operation of the memory cell structure of the flash memory device illustrated in FIG. 12. Particularly, FIG. 16 is a graph of drain electric current (I_{P}) with respect to gate source voltage (V_{GS}).

In the memory cell structure of the flash memory device, the first gate electrode 12 included polysilicon, the hole tunnel insulating pattern 27 included silicon oxide and had a thickness of about 3.5 nm, the charge trapping pattern 32 included silicon nitride and had a thickness of about 10 nm, the electron tunnel insulating pattern 47 included aluminum oxide and had a thickness of about 10 nm, and the channel 62 included IGZO and had a thickness of about 10 nm.

A programming pulse of +25V was applied to the first gate electrode 12 included in the memory cell structure of the flash memory device for about 1 ms, and an erasing pulse of +15V was applied to the first gate electrode 12 for about 100 ms.

Referring to FIG. 16, as the programming pulse is applied, a threshold voltage of the memory cell structure is shifted in a positive direction by about 4.9V, and as the erasing pulse is applied, the threshold voltage of the memory cell structure is shifted in a negative direction by about 4.9V, so that the threshold voltage returns to an initial state.

The program operation and the erase operation to the memory cell structure of the flash memory device is performed effectively, and the memory cell structure of the flash memory device has a memory window of about 4.9V.

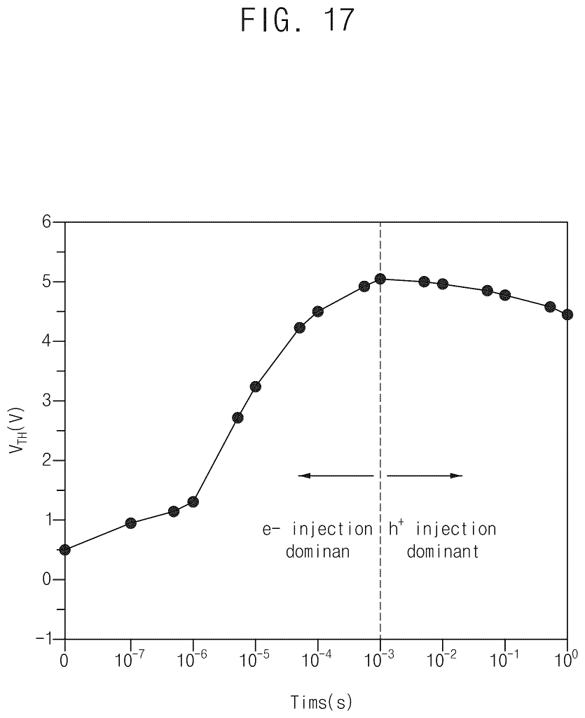

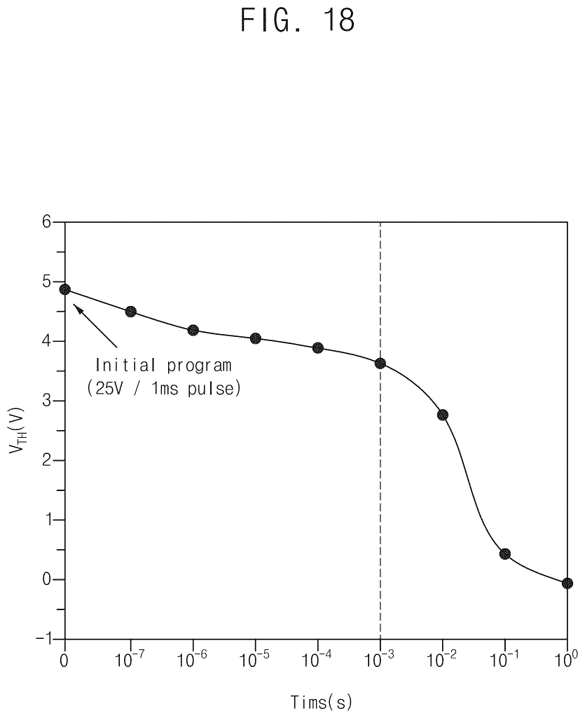

FIGS. 17 and 18 are graphs illustrating characteristics of program operation and erase operation of the memory cell structure of the flash memory device illustrated in FIG. 12. Particularly, FIGS. 17 and 18 are graphs illustrating a change of the threshold voltage over a time of a voltage applied to the first gate electrode 12.

FIG. 17 is a graph illustrating a change of the threshold voltage (VTH) when a program voltage of about +25V is applied to the first gate electrode 12, and FIG. 18 is a graph illustrating a change of the threshold voltage when an erase voltage of about +15V is applied to the first gate electrode 12.

Referring to FIG. 17, when the program voltage is applied, the threshold voltage rapidly increases to about 4.9V up to about 1 ms, and then gradually decreases.

FIG. 17 means that electrons in the channel 62 may move to the charge trapping pattern 32 through the electron tunnel insulating pattern 47 by the program voltage up to about 1 ms, and then holes in the first gate electrode 12 may gradually move to the charge trapping pattern 32 through the hole tunnel insulating pattern 27 by the program voltage.

Referring to FIG. 18, the threshold voltage gradually decreases to about 3.7V up to about 1 ms, and then the threshold voltage rapidly decreases to about 0V.

The graph of FIG. 17 indicates that holes in the first gate electrode 12 may move to the charge trapping pattern 32 through the hole tunnel insulating pattern 27 by the erase voltage after about 1 ms.

As illustrated above with reference to FIGS. 13 to 15, in the memory cell structure of the flash memory device illustrated in FIG. 12, when the program voltage with a relatively high voltage is applied, even though some of the holes in the first gate electrode 12 may move to the charge trapping pattern 32 through the hole tunnel insulating pattern 27, for at least a period of time, a current density of the electrons moving through the electron tunnel insulating pattern 47 may be greater than a current density of the holes moving through the hole tunnel insulating pattern 27, so that the program operation may be performed.

When the erase voltage with a relatively low voltage is applied, even though some of the electrons in the channel 62 may move to the charge trapping pattern 32 through the electron tunnel insulating pattern 47, after at least a period of time, an amount of the holes moving through the hole tunnel insulating pattern 27 may be greater than an amount of the electrons moving through the electrons tunnel insulating pattern 47, so that the erase operation may be performed.

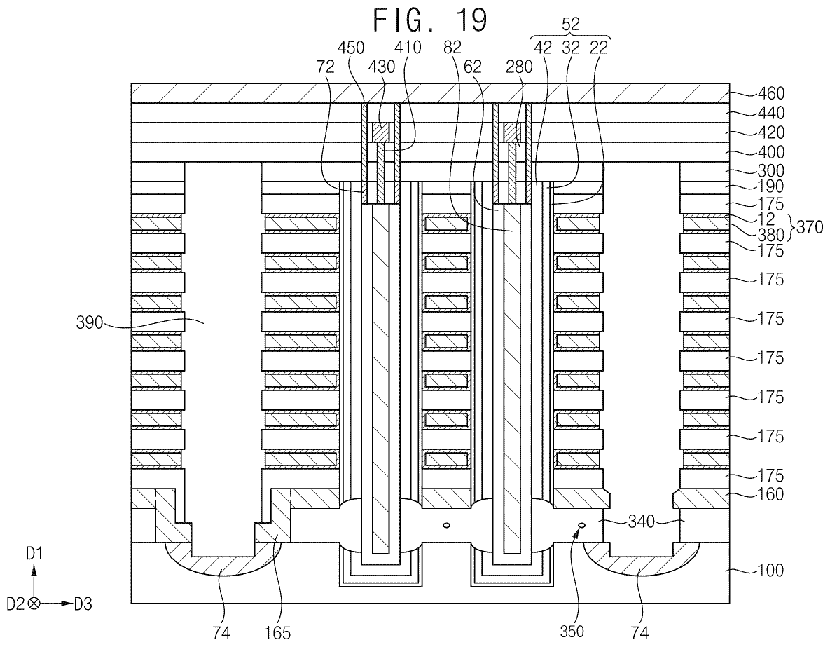

FIG. 19 is a cross-sectional view illustrating a vertical NAND flash memory device according to one or more embodiments. The vertical NAND flash memory device may include a plurality of strings each of which may include a plurality of memory cell structures of FIG. 1 sequentially stacked in a vertical direction, and thus repeated explanations are omitted herein.

Hereinafter, the vertical direction substantially perpendicular to an upper surface of a substrate may be referred to as a first direction D1, and two directions crossing each other among horizontal directions substantially parallel to the upper surface of the substrate may be referred to as second and third directions D2 and D3, respectively. In one or more embodiments, the second and third directions D2 and D3 may be substantially perpendicular to each other. Each of the first to third directions D1, D2 and D3 may include both a direction indicated by an arrow and a direction inverse thereto, in the drawings.

Referring to FIG. 19, the vertical NAND flash memory device may include the channel 62 on a substrate 100, the first memory structure 52, a gate electrode structure 370, the second gate electrode 82, and the first and second source/drain patterns 72 and 74.

In addition, the vertical NAND flash memory device may include a support layer 160, a support pattern 165, a first insulating pattern 175, a second insulating pattern 280, a channel connection pattern 340, a division pattern 390, a first contact plug 410, a second contact plug 450, a first wiring 430, a second wiring 460, a first insulating interlayer 190, a second insulating interlayer 300, a third insulating interlayer 400, a fourth insulating interlayer 420, and a fifth insulating interlayer 440, and a sixth insulating interlayer.

The substrate 100 may include a semiconductor material, e.g., silicon, germanium, silicon-germanium, etc., or a III-V group compound semiconductor, e.g., GaP, GaAs, GaSb, etc. In some example embodiments, the substrate 100 may be a silicon-on-insulator (SOI) substrate or a germanium-on-insulator (GOI) substrate.

The second gate electrode 82 may have a pillar shape extending in the first direction D1 on the substrate 100. In one or more embodiments, a plurality of second gate electrodes 82 may be spaced apart from each other in each of the second and third directions D2 and D3.

The channel 62 may have a cup shape extending in the first direction D1 and disposed on and covering a sidewall and a lower surface of the second gate electrode 82. In one or more embodiments, a plurality of channels 265 may be spaced apart from each other in each of the second and third directions D2 and D3, which may form a channel array.

The first memory structure 52 may be disposed on and cover an outer sidewall of the channel 62. In one or more embodiments, the first memory structure 52 may include an upper portion which may have a cylindrical shape and may be disposed on and cover an upper portion of an outer sidewall of the channel 62, and a lower portion which may have a cup shape and may be disposed on and cover a lower portion of the outer sidewall and a lower surface of the channel 62.

Each of the upper and lower portions of the first memory structure 52 may include the blocking pattern 42, the charge trapping pattern 32 and the tunnel insulating pattern 22, which may be sequentially stacked from the outer sidewall and/or the lower surface of the channel 62.

The channel 62 and the first memory structure 52 may collectively form a memory channel structure, and a plurality of memory channel structures may be spaced apart from each other in each of the second and third directions D2 and D3.

The second insulating pattern 280 may contact upper surfaces of the second gate electrode 82 and the channel 62 and an inner sidewall of the first memory structure 52. The second insulating pattern 280 may include an insulating material, e.g., silicon oxide, silicon nitride, etc.

The first source/drain pattern 72 may extend through the second insulating pattern 280 and may contact the upper surface of the channel 62. In one or more embodiments, the first source/drain pattern 72 may have a ring shape, or a hollow cylindrical shape.

The gate electrode structure 370 may be adjacent to and surround the memory channel structures, and a plurality of gate electrode structures 370 may be spaced apart from each other in the first direction D1 to form an electrode structure stack. Each of the gate electrode structures 370 may extend in the second direction D2, extension lengths in the second direction D2 of the gate electrode structures 370 may decrease from a lowermost level to an uppermost level, and thus the gate electrode structure stack may have a staircase shape.

The gate electrode structures 370 sequentially stacked in the first direction D1 may serve as a ground selection line (GSL), a word line and string selection line (SSL), corresponding to positions thereof. In one or more embodiments, one of the gate electrode structures 370 at a lowermost level may serve as the GSL, ones of the gate electrode structures 370 at an uppermost level and a level directly under the uppermost level may serve as the SSLs, respectively, and ones of the gate electrode structures 370 at a plurality of levels between the GSL and the SSL may serve as the word lines, respectively.

In one or more embodiments, the gate electrode structure 370 may include a third gate electrode 380 and the first gate electrode 12 which may be disposed on and cover upper and lower surfaces and a sidewall of the third gate electrode 380 facing a sidewall of the memory channel structure. The first gate electrode 12 may include a semiconductor material doped with impurities, and the third gate electrode 380 may include a metal, e.g., tungsten, or a metal nitride, e.g., titanium nitride.

The first insulating pattern 175 may be disposed between ones of the gate electrode structures 370 neighboring in the first direction D1, and the gate electrode structures 370 and the first insulating patterns 175 may collectively form a mold having a staircase shape. For example, the gate electrode structure stack including the gate electrode structures 370 stacked in the first direction D1, and the first insulating patterns 175 disposed between the gate electrode structures 370 may collectively form the mold. The first insulating pattern 175 may include, an oxide, e.g., silicon oxide.

In one or more embodiments, the mold, that is, the gate electrode structure stack may extend in the second direction D2, and a plurality of gate electrode structure stacks may be spaced apart from each other in the third direction D3. The division pattern 390 may be disposed between the molds, so that the molds may be separated from each other in the third direction D3. The division pattern 390 may include an oxide, e.g., silicon oxide.

The channel connection pattern 340 and the support layer 160 may be sequentially stacked in the first direction D1 on the substrate 100. The channel connection pattern 340 may be disposed on a lower portion of the outer sidewall of each of the channels 62, that is, between the upper and lower portions of the first memory structure 52, and may contact the outer sidewall of each of the channels 62 that may not be covered by the upper and lower portions of the first memory structure 52. Thus, some of the channels 62, e.g., ones of the channels 62 disposed in the same memory block may be electrically connected to each other. The channel connection pattern 340 may include, e.g., polysilicon doped with n-type impurities, and in some embodiments, an air gap 350 may be disposed in the channel connection pattern 340.

The second source/drain pattern 74 may be disposed at an upper portion of the substrate 100 and may contact a lower surface of the division pattern 390 and a lower surface of an end portion in the third direction D3 of the channel connection pattern 340. The second source/drain pattern 74 may be a region doped with, e.g., n-type impurities at the upper portion of the substrate 100.

The support layer 160 may be disposed between the channel connection pattern 340 and a lowermost one of the gate electrode structures 370. The support pattern 165 connected to the support layer 160 may extend through the channel connection pattern 340 and may contact an upper surface of the substrate 100. A plurality of support patterns 165 may be spaced apart from each other in the horizontal direction, and may have various layouts. The support layer 160 and the support pattern 165 may include, e.g., polysilicon doped with n-type impurities.

The first insulating interlayer 190 may be disposed on the substrate 100 and may be disposed on and cover the mold, the support layer 160 and the channel connection pattern 340, the second insulating interlayer 300 may be disposed on the first insulating interlayer 190, the second insulating pattern 280, the first source/drain pattern 72, the first memory structure 52 and the division pattern 390, and the third insulating interlayer 400 may be disposed on the second insulating interlayer 300 and the division pattern 390. The first contact plug 410 may extend through the second and third insulating interlayers 300 and 400 and the second insulating pattern 280, and may contact an upper surface of the second gate electrode 82.

The fourth insulating interlayer 420 may be disposed on the third insulating interlayer 400 and the first contact plug 410, and the first wiring 430 may extend through the fourth insulating interlayer 420 and may contact an upper surface of the first contact plug 410.

The fifth insulating interlayer 440 may be disposed on the fourth insulating interlayer 420 and the first wiring 430, and the second contact plug 450 may extend through the second to fourth insulating interlayers 300, 400 and 420, and may contact an upper surface of the first source/drain pattern 72.

The sixth insulating interlayer may be disposed on the fifth insulating interlayer 440 and the second contact plug 450, and the second wiring 460 may extend through the sixth insulating interlayer and may contact an upper surface of the second contact plug 450.

In one or more embodiments, the second wiring 460 may extend in the third direction D3, and a plurality of second wirings 460 may be spaced apart from each other in the second direction D2. The second wiring 460 may serve as a bit line of the vertical NAND flash memory device.

Each of the first to fifth insulating interlayers 190, 300, 400, 420 and 440 and the sixth insulating interlayer may include an oxide, e.g., silicon oxide or a low-k dielectric material, and each of the first and second wirings 430 and 460 and the first and second contact plugs 410 and 450 may include, e.g., a metal, a metal nitride, a metal silicide, etc.

As illustrated above with reference to FIGS. 1 to 6, in the vertical NAND flash memory device, a program voltage and an erase voltage may be applied to the gate electrode structure 370 including the first gate electrode 12, a ground voltage may be applied to the second gate electrode 82, and thus a portion of the first memory structure 52 that may overlap in the horizontal direction with the gate electrode structure 370 and the second gate electrode 82 may be programmed or erased.

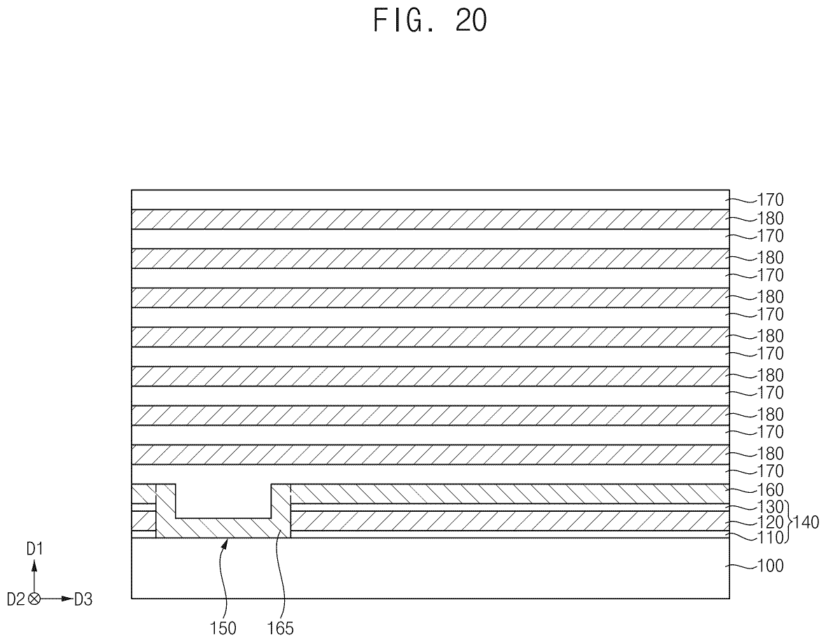

FIGS. 20 to 27 are cross-sectional views illustrating a method of manufacturing a vertical NAND flash device according to one or more embodiments.

Referring to FIG. 20, a sacrificial layer structure 140 may be formed on the substrate 100, the sacrificial layer structure 140 may be partially removed to form a first opening 150 exposing the upper surface of the substrate 100, and a support layer 160 may be formed on the substrate 100 and the sacrificial layer structure 140 to at least partially fill the first opening 150.

The sacrificial layer structure 140 may include a first sacrificial layer 110, a second sacrificial layer 120, and a third sacrificial layer 130 sequentially stacked in the first direction D1 on the substrate 100. Each of the first and third sacrificial layers 110 and 130 may include an oxide, e.g., silicon oxide, and the second sacrificial layer 120 may include an insulating nitride, e.g., silicon nitride.

The support layer 160 may include a material having an etching selectivity with respect to the first to third sacrificial layers 110, 120 and 130, e.g., polysilicon doped with n-type impurities or undoped polysilicon. The support layer 160 may be conformally formed, and thus a first recess may be formed on a portion of the support layer 160 in the first opening 150. Hereinafter, the portion of the support layer 160 in the first opening 150 may be referred to as a support pattern 165.

A first insulating layer 170 may be formed on the support layer 160 to fill the first recess, and an upper portion of the first insulating layer 170 may be planarized. A planarization process may include, e.g., a chemical mechanical (CMP) process and/or an etch back process.

A fourth sacrificial layer 180 and an additional first insulating layer 170 may be alternately and repeatedly stacked in the first direction D1 on the first insulating layer 170, so that a mold layer may be formed on the support layer 160. The first insulating layer 170 may include an oxide, e.g., silicon oxide, and the fourth sacrificial layer 180 may include a material having a relatively high etching selectivity with respect to the first insulating layer 170, e.g., an insulating nitride, such as silicon nitride.

An etching process may be performed on the first insulating layer 170 and the fourth sacrificial layer 180 using a photoresist pattern as an etching mask, and a trimming process for reducing an area of the photoresist pattern may also be performed. The etching process and the trimming process may be alternately and repeatedly performed, so that a mold having a staircase shape including a plurality of step layers each of which may include the fourth sacrificial layer 180 and the first insulating layer 170 sequentially stacked may be formed on the substrate 100.

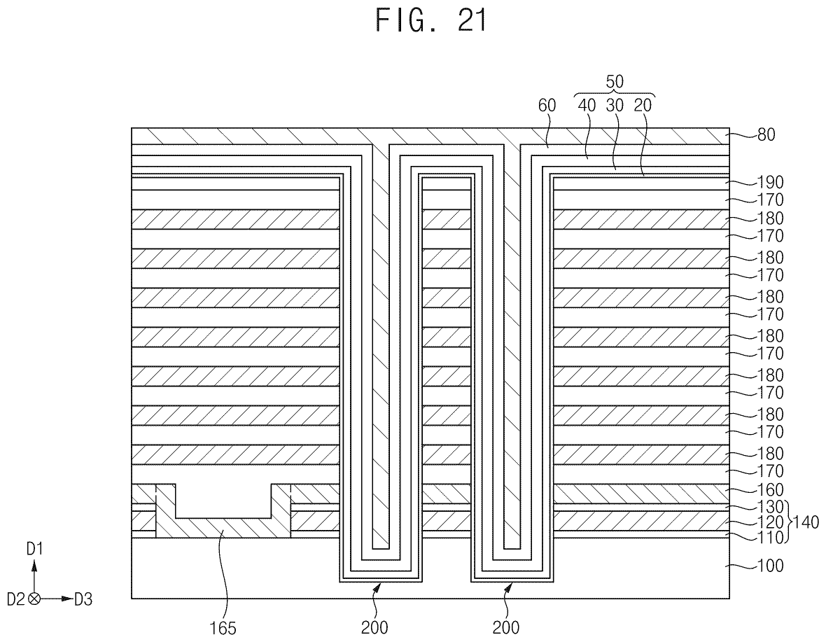

Referring to FIG. 21, a first insulating interlayer 190 may be formed on the substrate 100 to be disposed on and cover the mold, and a dry etching process may be performed to form a hole 200 extending through the first insulating interlayer 190, the mold, the support layer 160 and the sacrificial layer structure 140 and exposing an upper surface of the substrate 100.

In one or more embodiments, the dry etching process may be performed until the hole 200 exposes the upper surface of the substrate 100, and further the hole 200 may extend through the upper portion of the substrate 100. A plurality of holes 200 may be spaced apart from each other in each of the second and third direction D2 and D3 to define a hole array.

A first memory structure layer 50 and a channel layer 60 may be sequentially stacked on a sidewall of the hole 200, the upper surface of the substrate 100 exposed by the hole 200 and an upper surface of the first insulating interlayer 190, and a second gate electrode layer 80 may be formed on the channel layer 60 to fill the hole 200.

In one or more embodiments, the first memory structure layer 50 may include a tunnel insulating layer 20, a charge trapping layer 30, and a blocking layer 50 sequentially stacked.

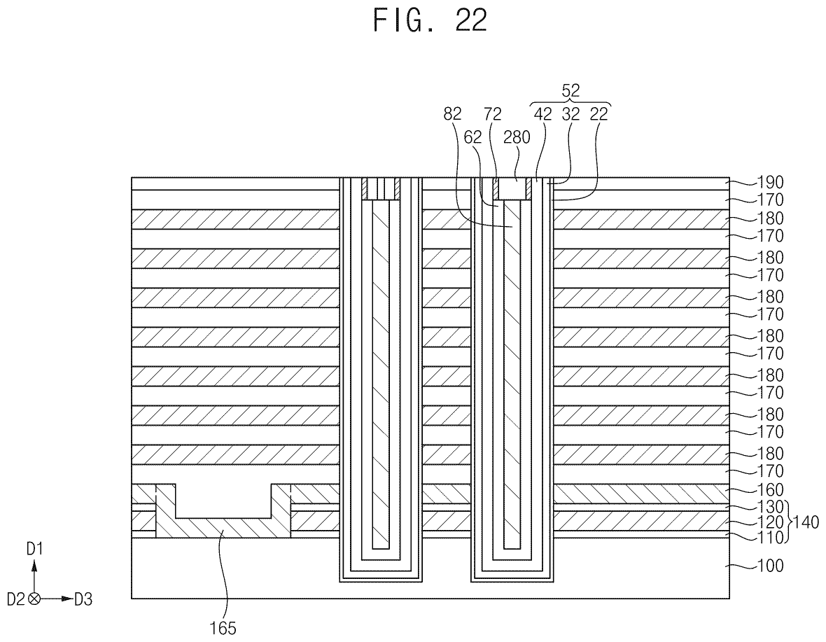

Referring to FIG. 22, a planarization process may be performed on the second gate electrode layer 80, the channel layer 60 and the first memory structure layer 50 until the upper surface of the first insulating interlayer 190 is exposed, so that a second gate electrode 82, a channel 62 and a first memory structure 52 may be formed, and the first memory structure 52 may include a tunnel insulating pattern 22, a charge trapping pattern 32 and a blocking pattern 42 sequentially stacked from the sidewall and a lower surface of the hole 200.

The planarization process may include, e.g., a CMP process and or an etch back process.

As the hole array is defined by the holes 200 in which the channel 62 and the first memory structure 52 are formed, the channels 62 and the first memory structures 52 in the holes 200 may also define a channel array and a first memory structure array, respectively.

Upper portions of the channel 62 and the second gate electrode 82 may be removed to form a second recess, a second insulating layer may be formed on the second gate electrode 82, the channel 62, the first memory structure 52 and the first insulating interlayer 190 to fill the second recess, and the second insulating layer may be planarized until the upper surface of the first insulating interlayer 190 is exposed, so that a second insulating pattern 280 may be formed to contact an upper inner sidewall of the first memory structure 52.

A pad 72 may be formed through a portion of the second insulating pattern 280 to contact an upper surface of the channel 62. The pad 72 may act the same function as the first source/drain pattern 72 illustrated in FIG. 1, and thus the pad 72 may also be referred to as the first source/drain pattern 72.

In one or more embodiments, the pad 72 may have a ring shape.

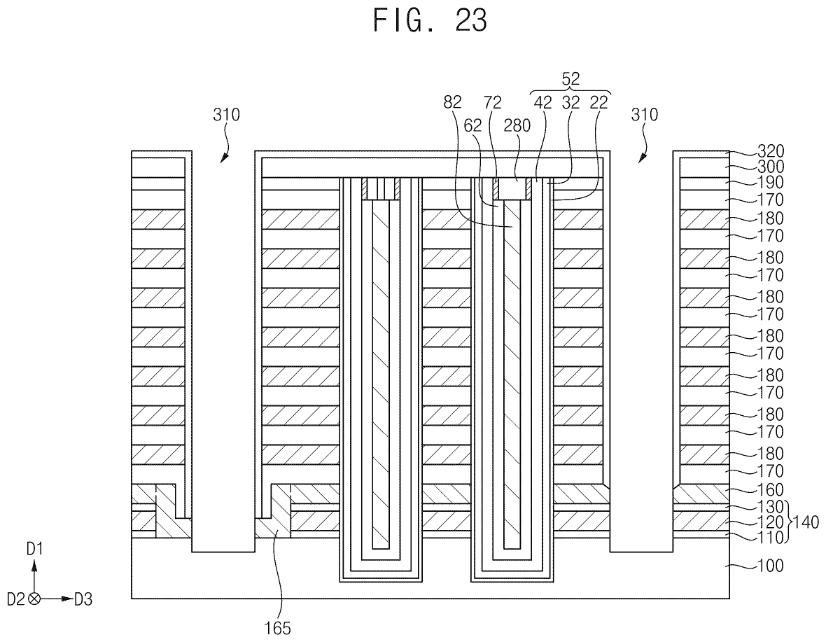

Referring to FIG. 23, a second insulating interlayer 300 may be formed on the first insulating interlayer 190, the pad 72, the second insulating pattern 280 and the first memory structure 52, and a dry etching process may be performed to form a second opening 310 extending partially through the first and second insulating interlayers 190 and 300 and the mold.

In one or more embodiments, the dry etching process may be performed until the second opening 310 exposes an upper surface of the support layer 160 or the support pattern 165, and further the second opening 310 may extend through an upper portion of the support layer 160 or the support pattern 165. As the second opening 310 is formed, the first insulating layer 170 and the fourth sacrificial layer 180 included in the mold may be exposed.

In one or more embodiments, the second opening 310 may extend in the second direction D2, and a plurality of second openings 310 may be spaced apart from each other in the third direction D3. As the second opening 310 is formed, the first insulating layer 170 may be divided into first insulating patterns 175 each of which may extend in the second direction D2, and the fourth sacrificial layer 180 may be divided into fourth sacrificial patterns 185 each of which may extend in the second direction D2.

A spacer layer may be formed on a sidewall of the second opening 310, the upper surface of the support layer 160 or the support pattern 165 exposed by the second opening 310, and the second insulating interlayer 300, and an anisotropic etching process may be performed on the spacer layer to remove a portion of the spacer layer on the upper surface of the support layer 160 or the support pattern 165 so that a spacer 320 may be formed, and that the upper surface of the support layer 160 or the support pattern 165 may be exposed again. In one or more embodiments, the spacer 320 may include, e.g., an undoped amorphous silicon, or an undoped polysilicon.

A portion of the support layer 160 and the support pattern 165 not covered and exposed by the spacer 320, and a portion of the sacrificial layer structure 140 under the portion of the support layer 160 and the support pattern 165 may be removed so that the second opening 310 may be enlarged downwardly in the first direction D1. Thus, the second opening 310 may expose the upper surface of the substrate 100, and further may extend through an upper portion of the substrate 100.

When the sacrificial layer structure 140 is partially removed, a sidewall of the second opening 310 may be covered by the spacer 320, and the spacer 320 may include a material different from that of the sacrificial layer structure 140, so that the first insulating pattern 175 and the fourth sacrificial pattern 185 included in the mold may not be removed.

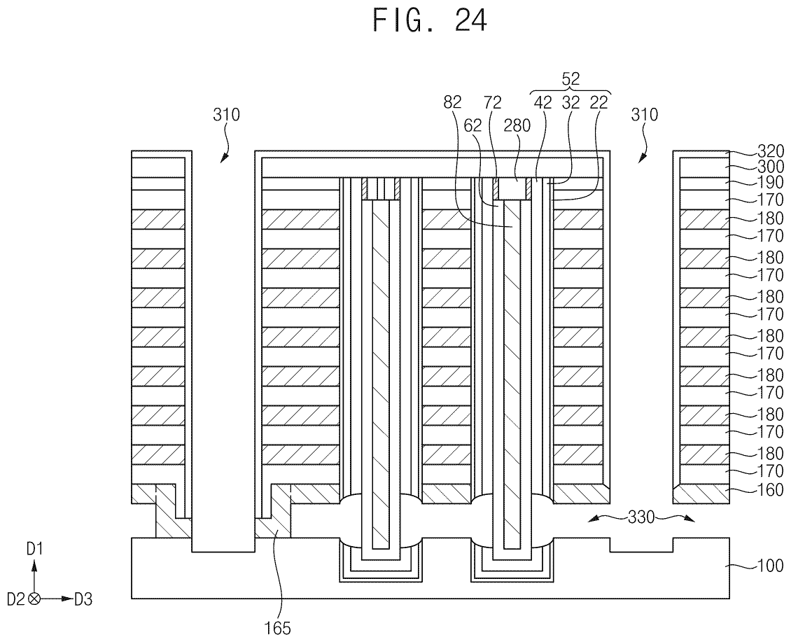

Referring to FIG. 24, the sacrificial layer structure 140 exposed by the second opening 310 may be removed, so that a first gap 330 may be formed to expose a lower outer sidewall of the first memory structure 52, and further a portion of the first memory structure 52 exposed by the first gap 330 may be removed so that a lower outer sidewall of the channel 62 may be exposed.

The sacrificial layer structure 140 and the first memory structure 52 may be partially removed by a wet etching process using, e.g., hydrofluoric acid (HF) and/or phosphoric acid (H₃PO₄). When the first gap 330 is formed, the support layer 160, the support pattern 165, the channel 62 and the second gate electrode 82 may not be removed, and may support the mold not to collapse.

As the first gap 330 is formed, the first memory structure 52 may be divided into an upper portion extending through the mold and covering a most portion of the outer sidewall of the channel 62, and a lower portion covering a lower surface of the channel 62 and disposed on the substrate 100.

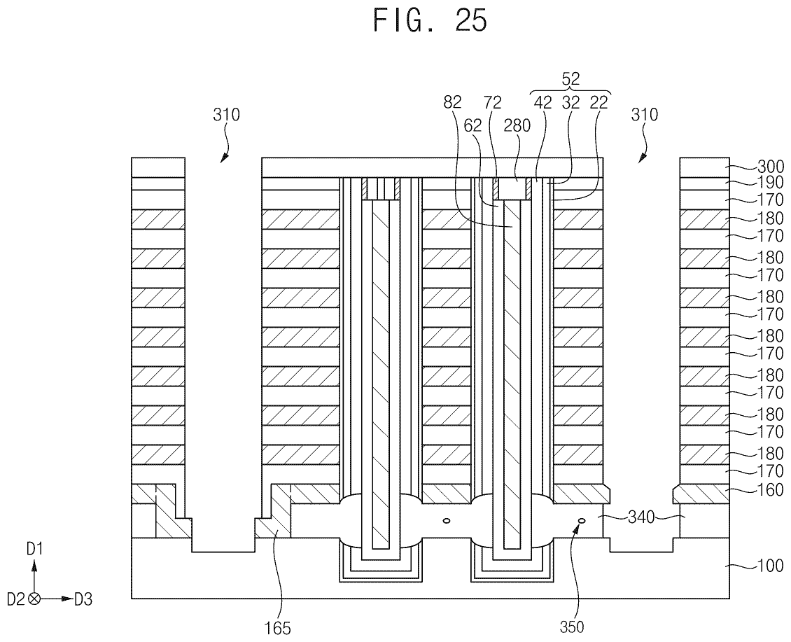

Referring to FIG. 25, the spacer 320 may be removed, and a channel connection pattern 340 may be formed to fill the first gap 330.

The channel connection pattern 340 may be formed by forming a channel connection layer on the substrate 100 and the second insulating interlayer 300 to fill the second opening 310 and the first gap 330, and performing an etch back process on the channel connection layer. The channel connection layer may include, e.g., polysilicon doped with n-type impurities. As the channel connection pattern 340 is formed, ones of the channels 62 forming the channel array between the second openings 310 neighboring in the third direction D3 may be connected to form a channel block.

In one or more embodiments, an air gap 350 may be formed in the channel connection pattern 340.

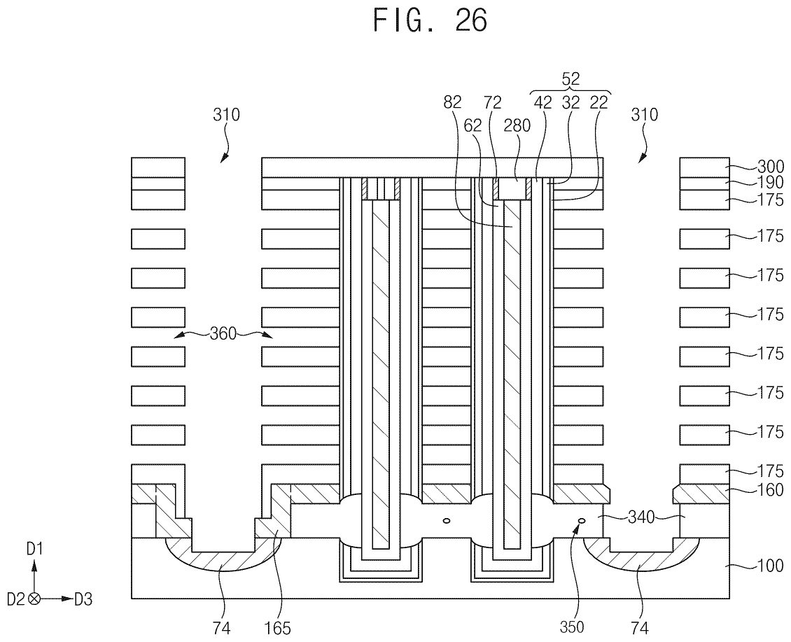

Referring to FIG. 26, e.g., n-type impurities may be doped into the upper portion of the substrate 100 exposed by the second opening 310 to form an impurity region 105.

The impurity region 105 may be configured as the second source/drain pattern 74 illustrated in FIG. 1, so that the impurity region may also be referred to as the second source/drain pattern 74.

The fourth sacrificial patterns 185 may be removed to form a second gap 360 exposing an outer sidewall of the first memory structure 52. The fourth sacrificial patterns 185 may be removed be by a wet etching process using, e.g., hydrofluoric acid (HF) and/or phosphoric acid (H₃PO₄) as an etching solution.

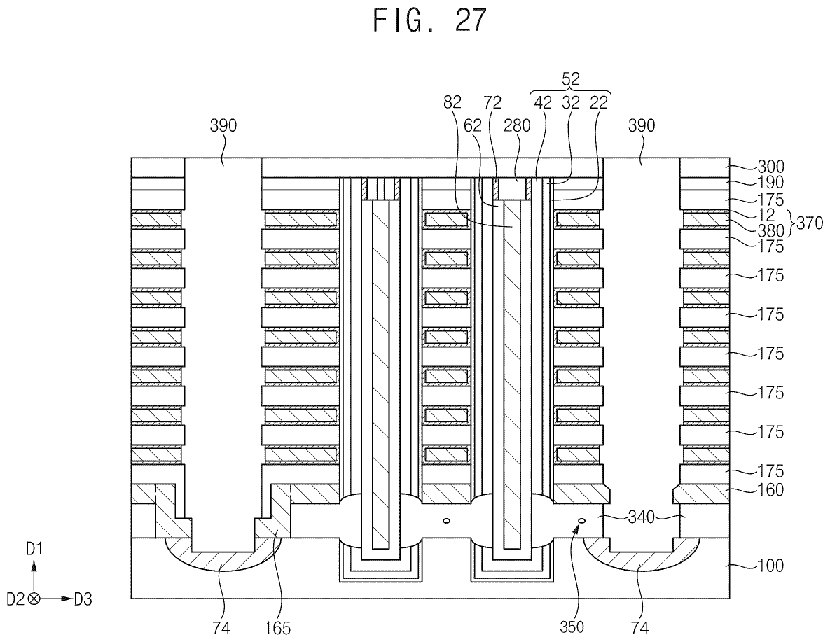

Referring to FIG. 27, a first gate electrode layer may be formed on the outer sidewall of the first memory structure 52 exposed by each of the second gaps 360, an inner wall of the second gap 360, a surface of the first insulating pattern 175, a sidewall of the support layer 160, a sidewall of the support pattern 165, a sidewall of the channel connection pattern 340, the upper surface of the substrate 100 and an upper surface of the second insulating interlayer 300, and a third gate electrode layer may be formed on the first gate electrode layer to fill the second gaps 360 and the second opening 310.

The first and third gate electrode layers may be partially removed to form first and third gate electrodes 12 and 380, respectively, in each of the second gaps 360, and the first and third gate electrodes 12 and 380 may collectively form a gate electrode structure 370. In example embodiments, the first and third gate electrode layers may be partially removed by a wet etching process.

In one or more embodiments, the gate electrode structure 370 may extend in the second direction D2, and a plurality of gate electrode structures 370 may be spaced apart from each other and stacked at a plurality of levels, respectively, to form a gate electrode structure stack. A plurality of gate electrode structure stacks may be spaced apart from each other in the third direction D3 by the second opening 310.

A division layer may be formed on the substrate 100 and the second insulating interlayer 300 to fill the second opening 310, and a planarization process may be performed on the division layer until the upper surface of the second insulating interlayer 300 is exposed. Thus, the division layer may be transformed into an division pattern 390 filling the second opening 310 and extending in the second direction D2.

Referring to FIG. 19 again, a third insulating interlayer 400 may be formed on the second insulating interlayer 300 and the division pattern 390, and a first contact plug 410 may be formed through the second and third insulating interlayers 300 and 400 and the second insulating pattern 280 to contact an upper surface of the second gate electrode 82.

A fourth insulating interlayer 420 may be formed on the third insulating interlayer 400 and the first contact plug 410, and a first wiring 430 may be formed through the fourth insulating interlayer 420 to contact an upper surface of the first contact plug 410.

A fifth insulating interlayer 440 may be formed on the fourth insulating interlayer 420 and the first wiring 430, and a second contact plug 450 may be formed through the first to fourth insulating interlayers 300, 400, 420 and 440 to contact an upper surface of the pad 72. For example, the second contact plug 450 may have a ring shape.

A sixth insulating interlayer may be formed on the fifth insulating interlayer 440 and the second contact plug 450, and a second wiring 460 may be formed through the sixth insulating interlayer to contact an upper surface of the second contact plug 450, so that the fabrication of the vertical NAND flash device may be completed.

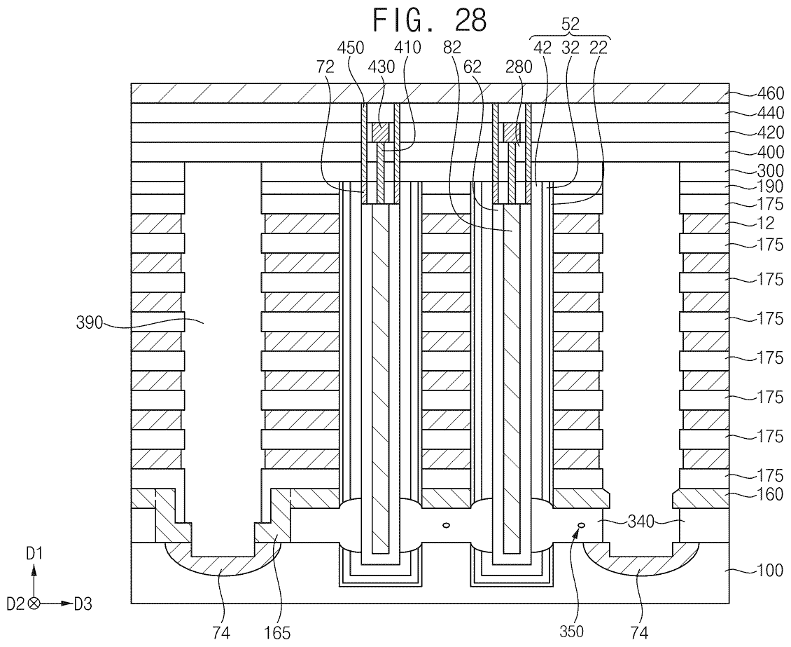

FIG. 28 is a cross-sectional view illustrating a vertical NAND flash memory device according to one or more embodiments. This vertical NAND flash memory device may be substantially the same as or similar to that of FIG. 19 except for the gate electrode structure, and thus repeated explanations are omitted herein.

Referring to FIG. 28, unlike that of the vertical NAND flash memory device of FIG. 19, the gate electrode structure 370 may include only the first gate electrode 12 that may include a doped or undoped semiconductor material, and may not include the third gate electrode 380 that may include a metal.

Thus, when the program voltage and the erase voltage are applied to the gate electrode structure 370, the electrons or holes included in an entire portion of the gate electrode structure 370, that is, an entire portion of the first gate electrode 12 may move to the charge trapping pattern 32 through the tunnel insulating pattern 22.

While embodiments have been described with reference to the figures, it will be understood by those of ordinary skill in the art that various changes in form and details may be made therein without departing from the spirit and scope as defined by the following claims and their equivalents.

What is claimed is:

1. A flash memory device comprising:
a first gate electrode comprising a semiconductor material;
a tunnel insulating pattern in contact with an upper surface of the first gate electrode;
a charge trapping pattern on the tunnel insulating pattern;
a blocking pattern on the charge trapping pattern;
a channel on the blocking pattern, the channel comprising an oxide semiconductor material;
source/drain patterns on the channel, the source/drain patterns being spaced apart from each other; and
a second gate electrode in contact with the channel, the second gate electrode being between adjacent source/drain patterns of the source/drain patterns.

2. The flash memory device according to claim 1, wherein a thickness of the tunnel insulating pattern is smaller than a thickness of the blocking pattern.

3. The flash memory device according to claim 2, wherein each of the tunnel insulating pattern and the blocking pattern comprises silicon oxide or a metal oxide.

4. The flash memory device according to claim 1, wherein the tunnel insulating pattern comprises silicon oxide, and the blocking pattern comprises a metal oxide.

5. The flash memory device according to claim 1, wherein the channel comprises indium gallium zinc oxide (IGZO).

6. The flash memory device according to claim 1, wherein based on a program voltage with a negative value being applied to the first gate electrode, electrons included in the first gate electrode is configured move to the charge trapping pattern through the tunnel insulating pattern.

7. The flash memory device according to claim 6, wherein based on a ground voltage being applied to the second gate electrode, and a potential of the channel is configured to be maintained at 0V.

8. The flash memory device according to claim 1, wherein based on an erase voltage with a positive value being applied to the first gate electrode, and holes included in the first gate electrode are configured to move to the charge trapping pattern through the tunnel insulating pattern.

9. The flash memory device according to claim 8, wherein based on a ground voltage being applied to the second gate electrode, and a potential of the channel is configured to be maintained at 0V.

10. A flash memory device comprising:
a gate electrode comprising a semiconductor material;
a hole tunnel insulating pattern in contact with an upper surface of the gate electrode;
a charge trapping pattern on the hole tunnel insulating pattern;
an electron tunnel insulating pattern on the charge trapping pattern;
a channel in contact with an upper surface of the electron tunnel insulating pattern, the channel comprising an oxide the semiconductor material; and
source/drain patterns on the channel, the source/drain patterns being spaced apart from each other,
wherein based on a program voltage with a first positive value being applied to the gate electrode, electrons included in the channel is configured to move to the charge trapping pattern through the electron tunnel insulating pattern and be trapped in the charge trapping pattern, to perform a program operation, and
wherein based on an erase voltage with a second positive value smaller than the first positive value being applied to the gate electrode, holes included in the gate electrode are configured to move to the charge trapping pattern through the hole tunnel insulating pattern, to perform an erase operation.

11. The flash memory device according to claim 10, wherein a thickness of the hole tunnel insulating pattern is smaller than a thickness of the electron tunnel insulating pattern.

12. The flash memory device according to claim 11, wherein each of the hole tunnel insulating pattern and the electron tunnel insulating pattern comprises silicon oxide or a metal oxide.

13. The flash memory device according to claim 10, wherein the hole tunnel insulating pattern comprises silicon oxide, and the electron tunnel insulating pattern comprises a metal oxide.

14. A flash memory device comprising:
a first gate electrode on a substrate, the first gate electrode extending in a vertical direction perpendicular to an upper surface of the substrate;
a channel in contact with a sidewall and a lower surface of the first gate electrode;
a memory structure comprising a blocking pattern, an electron trapping pattern, and a tunnel insulating pattern sequentially stacked in a horizontal direction parallel to the upper surface of the substrate from an outer sidewall of the channel; and
gate electrode structures spaced apart from each other in the vertical direction on the substrate, each of the gate electrode structures on the memory structure.

15. The flash memory device according to claim 14, wherein each gate electrode structure of the gate electrode structures comprises a second gate electrode that comprises a semiconductor material.

16. The flash memory device according to claim 15, wherein each gate electrode structure of the gate electrode structures further comprises a third gate electrode,
wherein the second gate electrode is on an upper surface, a lower surface, and a sidewall of the third gate electrode, and
wherein the third gate electrode comprises a metal.

17. The flash memory device according to claim 14, wherein a thickness of the blocking pattern is greater than a thickness of the tunnel insulating pattern.

18. The flash memory device according to claim 14, wherein the blocking pattern comprises a metal oxide, and the tunnel insulating pattern comprises silicon oxide.

19. The flash memory device according to claim 14, further comprising:
a first contact plug in contact with an upper surface of the first gate electrode; and
a first wiring in contact with an upper surface of the first contact plug, the first wiring being configured to apply a ground voltage to the first gate electrode.

20. The flash memory device according to claim 14, further comprising:
a first source/drain pattern in contact with an upper surface of the channel;
a bit line on the first source/drain pattern; and
a second source/drain pattern at an upper portion of the substrate.
